(19) United States
(12) Patent Application Publication
(10) Pub. No.: US 2015/0302899 A1
(43) Pub. Date: Oct. 22, 2015

(54) SEMICONDUCTOR MEMORY DEVICE

(71) Applicant: SK hynix Inc., Gyeonggi-do (KR)

(72) Inventor: Kwan-Weon KIM, Gyeonggi-do (KR)

(21) Appl. No.: 14/520,068

(22) Filed: Oct. 21, 2014

(30) Foreign Application Priority Data
Apr. 22, 2014 (KR) 10-2014-0047838

(51) Int. Cl. G11C 5/02; G11C 7/06; G11C 5/06

(52) U.S. Cl. CPC G11C 5/025; G11C 5/063; G11C 7/06

(57) ABSTRACT

A semiconductor memory device includes: a first memory region including a plurality of first memory cells, two or more of which are simultaneously selected by a single address, and stores a first single datum; and a second memory region including a plurality of second memory cells, each of which is selected by the single address, and stores a second single datum.

### CROSS-REFERENCE TO RELATED APPLICATIONS

The present application claims priority of Korean Patent Application No. 10-2014-0047838, filed on Apr. 22, 2014, which is incorporated herein by reference in its entirety.

### BACKGROUND

1. Field

Various exemplary embodiments of the present invention relate to a semiconductor design technology, and more particularly, to a semiconductor memory device capable of selectively securing stable data readout.

2. Description of the Related Art

In general, a semiconductor memory device includes a plurality of memory cells, each of which stores data representing ‘0’ or ‘1’.

FIG. 1 is a schematic diagram illustrating a memory cell of a typical semiconductor memory device.

FIG. 1 shows a memory cell of a general Dynamic Random Access Memory (DRAM) of 1-transistor-1-capacitor (1T1C) structure.

The transistor TR of the memory cell turns on/off coupling between a bit line BL and the capacitor C in response to a signal on a word line WL coupled thereto.

During data write operations of the memory cell, data is stored in the capacitor C according to the varying voltage levels of the bit line BL, representing data inputted from an exterior. During data read operations, it is determined whether the data stored in the capacitor C is ‘1’ or ‘0’ by reflecting the voltage level of the capacitor C to the bit line BL, and amplifying the reflected voltage level of the bit line BL with reference to a voltage level of a bit line bar BLB. The capacitor C needs to have enough capacity in order to stably readout stored data.

However, as the memory cell is miniaturized, area for the capacitor C decreases. Since the charge capacity of the capacitor C and the voltage sweeping range of the bit line BL become smaller, the data may not be stably readout. For this reason, research to improve the characteristics of the capacitor C have been carried out to secure stable data readout from the capacitor C.

### SUMMARY

Various exemplary embodiments of the present invention are directed to a semiconductor memory device capable of storing data in various ways for stable data readout.

In accordance with an embodiment of the present invention, a semiconductor memory device includes: a first memory region including a plurality of first memory cells, two or more of which are simultaneously selected by a single address, and stores a first single datum; and a second memory region including a plurality of second memory cells, each of which is selected by the single address, and stores a second single datum.

In accordance with another embodiment of the present invention, a semiconductor memory device includes: a first memory region including a plurality of first memory cells, two of which are simultaneously selected by a single address, and stores a first single datum; a second memory region including a plurality of second memory cells, four of which are simultaneously selected by a single address, and stores a second single datum; and a third memory region including a plurality of third memory cells, each of which is selected by a single address, and stores a third single datum.

### BRIEF DESCRIPTION OF THE DRAWINGS

FIG. 1 is a schematic diagram illustrating a memory cell of a general semiconductor memory device.

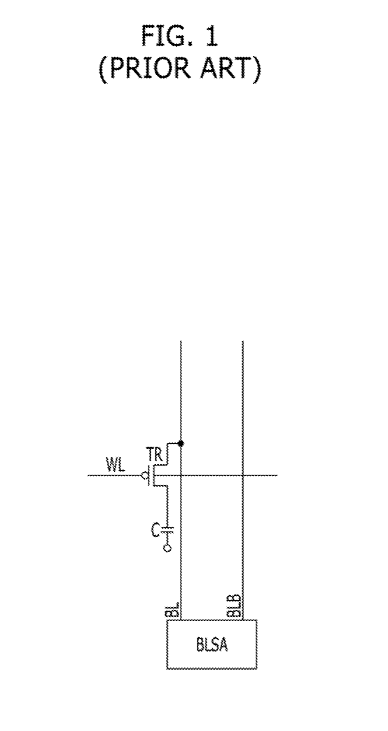

FIG. 2 is a circuit diagram illustrating a memory cell array of a semiconductor memory device in accordance with an exemplary embodiment of the present invention.

FIG. 3 is a waveform diagram illustrating an operation of a first memory region shown in FIG. 2.

FIG. 4 is a circuit diagram illustrating a memory cell array of a semiconductor memory device in accordance with an exemplary embodiment of the present invention.

FIG. 5 is a waveform diagram illustrating an operation of a first memory region shown in FIG. 4.

FIG. 6 is a circuit diagram illustrating a memory cell array of a semiconductor memory device in accordance with an exemplary embodiment of the present invention.

FIG. 7 is a waveform diagram illustrating an operation of a first memory region shown in FIG. 6.

FIG. 8 is a layout illustrating a semiconductor memory device in accordance with an exemplary embodiment of the present invention.

FIG. 9 is a layout illustrating a semiconductor memory device in accordance with an exemplary embodiment of the present invention.

FIG. 10 is a layout illustrating a semiconductor memory device in accordance with an exemplary embodiment of the present invention.

FIG. 11 is a waveform diagram illustrating an operation of a second memory region shown in FIGS. 2, 4 and 6.

### DETAILED DESCRIPTION

Exemplary embodiments of the present invention are described below in more detail with reference to the accompanying drawings. These embodiments are provided so that this disclosure is thorough and complete and fully conveys the scope of the present invention to those skilled in the art.

The accompanying drawings and the related description only show part of circuits as an example for clear description of the present invention, and therefore the scope of the present invention will not be limited by the examples of the description and the accompanying drawings but by the claims.

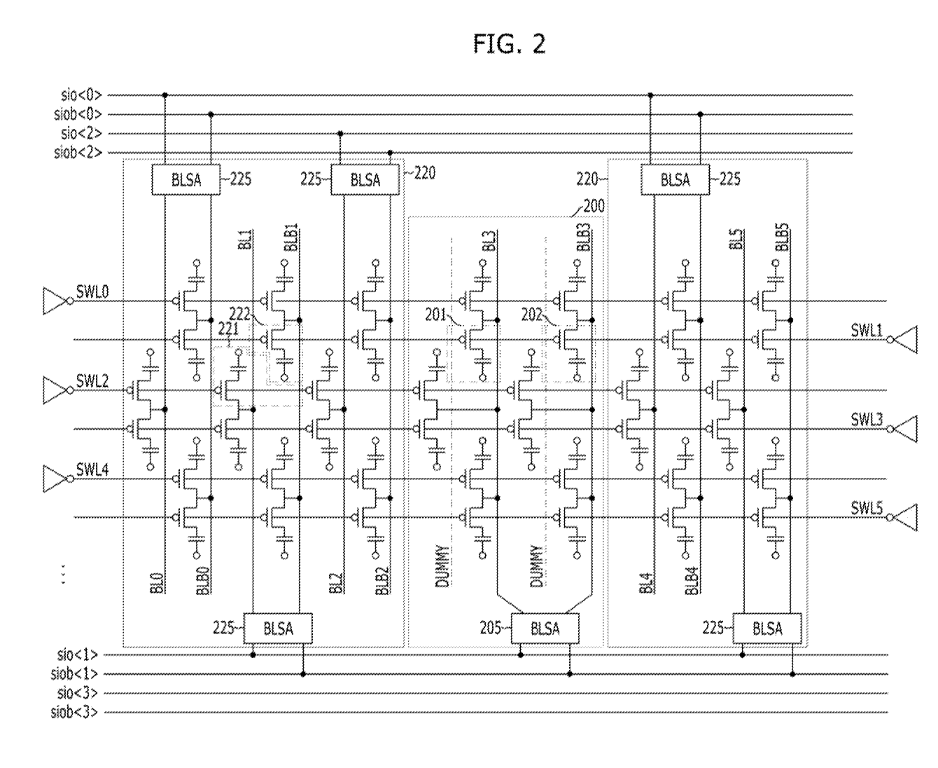

FIG. 2 a circuit diagram illustrating a memory cell array of a semiconductor memory device in accordance with an exemplary embodiment of the present invention.

Referring to FIG. 2, the memory cell array of the semiconductor memory device may include first and second memory regions 200 and 220. For example, the first memory region 200 may include a weighted sense amplifier 205, first and second weighted memory cells 201 and 202 electrically coupled to the weighted sense amplifier 205 and a single word line. For example, the second memory region 220 may include a non-weighted sense amplifier 225, and first and second non-weighted memory cells 221 and 222 each electrically coupled to the non-weighted sense amplifier 225 and different word lines.

The first memory region 200 may store a single datum in two or more memory cells simultaneously selected by the single word line according to a single address (not shown).

The first weighted memory cell 201 may be coupled with a word line SWL1 and bit line BL3 therebetween, and may store the data.

The second weighted memory cell 202 may be coupled with the word line SWL1 and a bit line bar BLB3 therebetween, and may store the inverted version of the data stored in the first weighted memory cell 201.

The weighted sense amplifier 205 may sense and amplify a level difference between the data stored in the first and second weighted memory cells 201 and 202 through the bit line BL3 and the bit line bar BLB3.

When the word line SWL1 is enabled in response to a row address (not shown) which is applied from an exterior, the first and second weighted memory cells 201 and 202 may be simultaneously selected since the first and second weighted memory cells 201 and 202 are commonly coupled with the word line SWL1 as described above. Therefore, the data stored in the second weighted memory cell 202 may be loaded on the bit line bar BLB3 when the data stored in the first weighted memory cell 201 is loaded on the bit line BL3.

The data stored in the first and second weighted memory cells 201 and 202 may have opposite levels to each other. For example, when the data stored in the first weighted memory cell 201 has a level corresponding to ‘1’, the data stored in the second weighted memory cell 202 has a level corresponding to ‘0’.

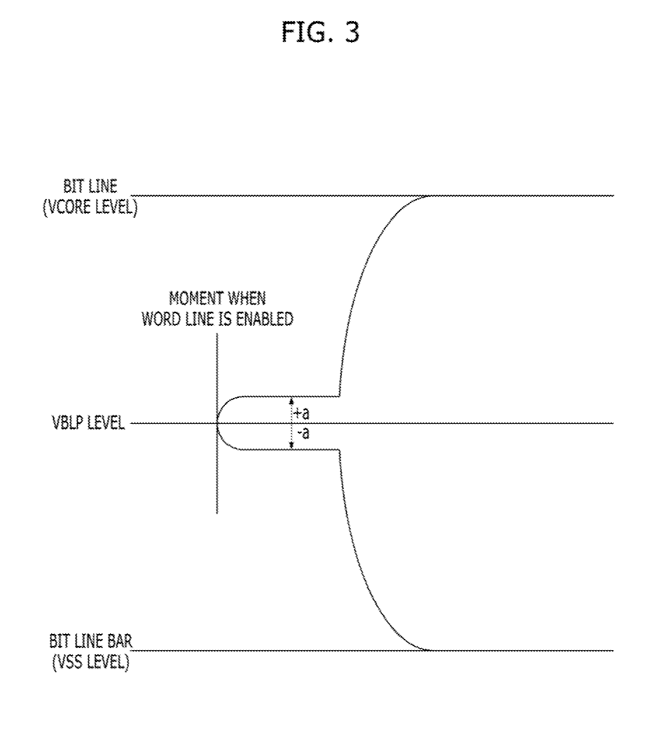

FIG. 3 is a waveform diagram illustrating an operation of the first memory region 200 shown in FIG. 2.

As shown in FIG. 3, in response to the activated word line SWL1, a voltage level of the bit line BL3 may increase by a predetermined amount of “+a” from a bit line precharge voltage VBLP, and a voltage level of the bit line bar BLB3 decreases by a predetermined amount of “−a” from the bit line precharge voltage VBLP. Therefore, a level difference between the bit line BL3 and the bit line bar BLB3 may be relatively large, and the weighted sense amplifier 205 may amplify the levels of the bit line BL3 and the bit line bar BLB3 to the core voltage VCORE and the ground voltage VSS by sensing the level difference.

The second memory region 220 may store a single datum in a single non-weighted memory cell selected by the corresponding single word line according to a single address (not shown).

The first and second non-weighted memory cells 221 and 222 may be coupled with the third word line SWL2 and a bit line BL1 therebetween, and the second word line SWL1 and a bit line bar BLB1 therebetween and stores the data, respectively, and the first and second non-weighted memory cells 221 and 222 may store individual data through the bit line BL1 and bit line bar BLB1 of the non-weighted sense amplifier 225, respectively.

The non-weighted sense amplifier 225 may sense and amplify a level difference between the data of the first non-weighted memory cell 221 and the bit line bar BLB1, and sense and amplify a level difference between the data of the second non-weighted memory cell 222 and the bit line BL1.

As described above, the first and second non-weighted memory cells 221 and 222 are coupled with the bit line BL1 and the third word line SWL2 therebetween and the bit line bar BLB1 and the second word line SWL1 therebetween, respectively. Therefore, when the second word line SWL2 is enabled in response to a row address (not shown) which is applied from an exterior, just the non-weighted memory cell 221 coupled with the bit line BL1 may be enabled. When the second word line SWL1 is enabled in response to the row address (not shown) which is applied from an exterior, just the non-weighted memory cell 222 coupled with the bit line bar BLB1 may be enabled.

One of the non-weighted memory cells 221 and 222 may be selected in response to a single address. Therefore, no data is loaded on the bit line bar BLB1 when the data of the non-weighted memory cell 221 is loaded on the bit line BL1. Similarly, no data is loaded on the bit line BL1 when the data of the non-weighted memory cell 222 is loaded on the bit line bar BLB1.

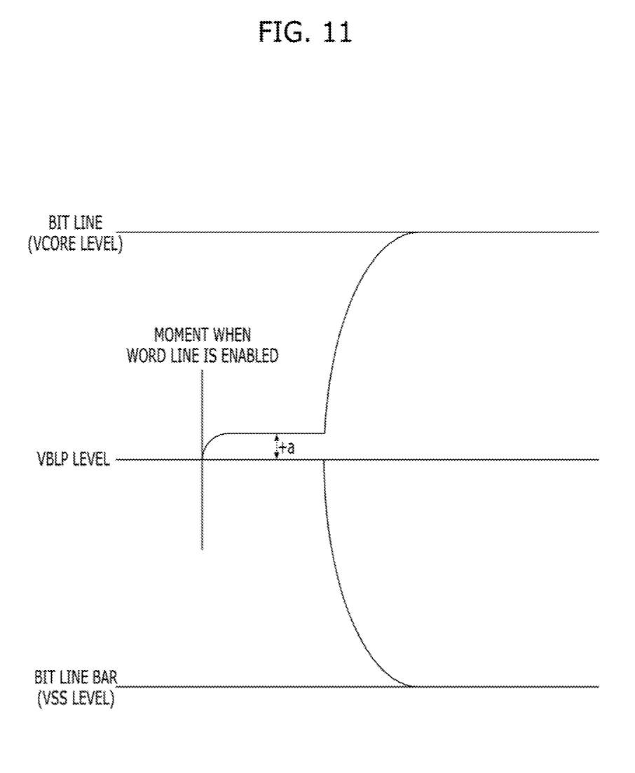

FIG. 11 is a waveform diagram illustrating an operation of the second memory region 220 shown in FIG. 2.

For example as shown in FIG. 11, in response to the activated first word line SWL2 when the data stored in the non-weighted memory cell 221 coupled with the bit line BL1 has a level corresponding to ‘1’, a level of the bit line BL1 Increases by the predetermined amount of “+a” from a bit line precharge voltage VBLP, and the voltage level of the bit line bar BLB1 may maintain the bit line precharge voltage VBLP. Therefore, a level difference between the bit line BL1 and the bit line bar BLB1 may be relatively small, and the non-weighted sense amplifier 225 may amplify the levels of the bit line BL1 and the bit line bar BLB1 to the core voltage VCORE and the ground voltage VSS by sensing the level difference.

Referring back to FIG. 2, the weighted memory cells in the first memory region 200 and the non-weighted memory cells in the second memory region 220 may be differently disposed. For example, in the first memory region 200, the weighted memory cells may be disposed at every cross point of the word lines SWL0 to SWL5 and the bit lines BL3 and BLB3 with reference to the single weighted sense amplifier 205. For example, in the second memory region 220, pairs of the non-weighted memory cells may be alternately disposed between the bit line BL1 and the bit line bar BLB1 at cross points formed by pairs of the word lines and the bit line BL1 and the bit line bar BLB1 with reference to the single non-weighted sense amplifier 225. The first and second (SWL0 and SWL1), the third and fourth (SWL2 and SWL3), and the fifth and sixth (SWL4 and SWL5) word lines in order of sequence may be the pairs of the word lines. For example, with reference to the pair of third and fourth word lines SWL2 and SWL3, the non-weighted memory cells may be disposed only on the bit lines BL0, BL1, BL2, BL4 and BL5. For example, with reference to the pairs of first and second, and fifth and sixth word lines SWL0 and SWL1, and SWL4 and SWL5, the non-weighted memory cells may be disposed only on the bit line bars BLB0, BLB1, BLB2, BLB4 and BLB5.

Therefore, in the first memory region 200, every single word line may simultaneously couple the first and second weighted memory cells 201 and 202, respectively, to the bit line BL3 and the bit line bar BLB3 of the weighted sense amplifier 205, which means that the data stored in the first and second weighted memory cells 201 and 202 may be simultaneously loaded on the bit line BL3 and the bit line BLB3 of the weighted sense amplifier 205. On the other hand, in the second memory region 220, each of the pairs of word lines SWL0 and SWL1, SWL2 and SWL3, and SWL4 and SWL5 may couple the pair of the non-weighted memory cells exclusively to one of the bit line BL0 to BL2 and the bit line BLB0 to BLB2, which means that the data stored in the first and second non-weighted memory cells 221 and 222 may be exclusively and alternately loaded between the bit line BL0 to BL2 and the bit line BLB0 to BLB2 of the non-weighted sense amplifier 225.

The first and second memory regions 200 and 220 may perform operations respectively in response to the activated one of the word lines SWL0 to SWL5. Therefore, both of the first and second memory regions 200 and 220 may be controlled through a single control operation.

As can be seen from FIGS. 3 and 11, the weighted sense amplifier 205 of the first memory region 200 may sense twice or more times the voltage level of the bit lines versus the non-weighted sense amplifier 225 of the second memory region 220. Therefore, the reliability of the data readout from the first memory region 200 may be twice or more as great as the reliability of the data readout from the second memory region 220.

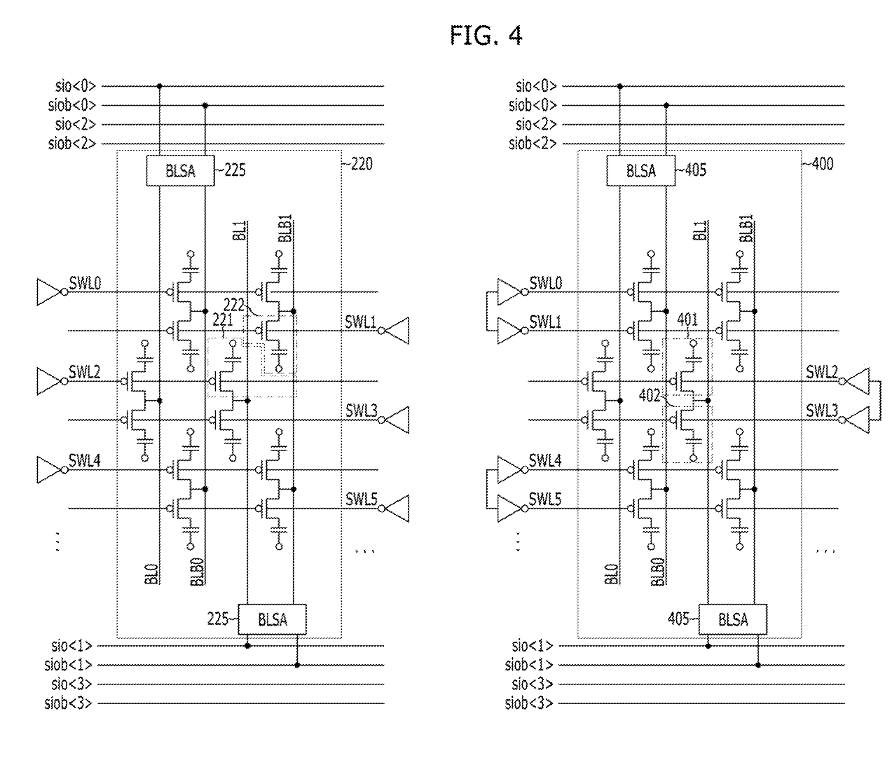

FIG. 4 is a circuit diagram illustrating a memory cell array of a semiconductor memory device in accordance with an exemplary embodiment of the present invention.

Referring to FIG. 4, the memory cell array of the semiconductor memory device may include first and second memory regions 400 and 220. For example, the first memory region 400 may include a weighted sense amplifier 405, and first and second weighted memory cells 401 and 402 alternately coupled to one of bit lines BL3 and BLB3 of the weighted sense amplifier 405, and coupled to a pair of word lines.

The second memory region 220 may be the same as the second memory region described with reference to FIGS. 2 and 11.

The connection relationships among the memory cells, the word lines, and the sense amplifier between the first and second memory regions 400 and 220 may be the same as each other except that the word lines of each of the pairs of word lines SWL0 and SWL1, SWL2 and SWL3, and SWL4 and SWL5 are simultaneously activated according to a single address in the first memory region 400.

The first memory region 400 may store a single datum in two or more memory cells simultaneously selected by the pair of word lines according to a single address (not shown).

The first weighted memory cell 401 may be coupled with the third word line SWL2 and a bit line BL1 therebetween, and may store the data.

The second weighted memory cell 402 may be coupled with the fourth word line SWL3 and the bit line BL1 therebetween, and may store the same data as the data stored in the first weighted memory cell 401.

The third and fourth word lines SWL2 and SWL3 may be simultaneously selected and enabled in response to a single address. In other words, the first and second weighted memory cells 401 and 402 may be simultaneously selected or not.

For example, in the first memory region 400, the pairs of the weighted memory cells 401 and 402 may be alternately disposed between the bit line BL1 and the bit line bar BLB1 at cross points formed by the pairs of the word lines SWL0 and SWL1, SWL2 and SWL3, and SWL4 and SWL5 and the bit line BL1 and the bit line bar BLB1 with reference to the single weighted sense amplifier 405. For example, with reference to the pair of third and fourth word lines SWL2 and SWL3, a pair of the first and second weighted memory cells 401 and 402 may be disposed on the bit lines BL0 and BL1. For example, with reference to the pairs of first and second word lines SWL0 and SWL1, the first and second weighted memory cells 401 and 402 may be disposed on the bit line bars BLB0 and BLB1.

The weighted sense amplifier 405 may sense and amplify a level difference between the data of the first and second weighted memory cells 401 and 402 through the bit line BL1, and a bit line bar BLB1. Although the first weighted memory cell 401 is coupled with the third word line SWL2, and the second weighted memory cell 402 is coupled with the fourth word line SWL3 as described above, the first and second weighted memory cells 401 and 402 are coupled with substantially a single word line since the pair of the third and fourth word lines SWL2 and SWL3 are simultaneously enabled or disabled. In other words, when the pair of the third and fourth word lines SWL2 and SWL3 are simultaneously enabled in response to a row address (not shown) applied from an exterior, the first and second weighted memory cell 401 and 402 may be simultaneously selected. Since the first and second weighted memory cell 401 and 402 are coupled with the bit line BL2, the data of the second weighted memory cell 402 may be loaded on the bit line BL1 when the data of the first weighted memory cell 401 is loaded on the bit line BL1.

The data stored in the first weighted memory cell 401 and the data stored in the second weighted memory cell 402 have the same level. For example, when the data stored in the first weighted memory cell 401 has a core voltage VCORE level corresponding to ‘1’, the data stored in the second weighted memory cell 402 also has the core voltage VCORE level corresponding to ‘1’.

Therefore, in the first memory region 400, each of the pair of word lines SWL0 and SWL1, SWL2 and SWL3, and SWL4 and SWL5 may simultaneously couple the first and second weighted memory cells 201 and 202 commonly to one of the bit line BL0 and BL1 and the bit line bar BLB0 and BLB1 of the weighted sense amplifier 405, which means that the data stored in the first and second weighted memory cells 401 and 402 may be simultaneously loaded on the bit line BL0 and BL1 of the weighted sense amplifier 405. On the other hand, in the second memory region 220, each of the pairs of word lines SWL0 and SWL1, SWL2 and SWL3, and SWL4 and SWL5 may couple the pair of the non-weighted memory cells exclusively to one of the bit line BL0 to BL2 and the bit line BLB0 to BLB2, which means that the data stored in the first and second non-weighted memory cells 221 and 222 may be exclusively and alternately loaded between the bit line BL0 to BL2 and the bit line BLB0 to BLB2 of the non-weighted sense amplifier 225.

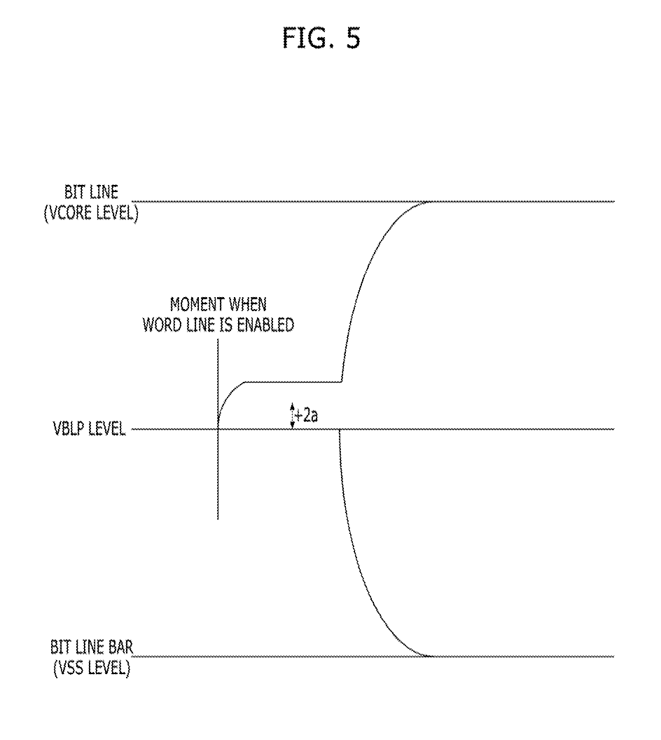

FIG. 5 is a waveform diagram illustrating an operation of a first memory region shown in FIG. 4.

As shown in FIG. 5, in response to the activated pair of third and fourth word lines SWL2 and SWL3, a voltage level of the bit line BL1 may increase by twice the predetermined amount of “+2a” from a bit line precharge voltage VBLP, and a voltage level of the bit line bar BLB1 may maintain the bit line precharge voltage VBLP. Therefore, a level difference between the bit line BL1 and the bit line bar BLB1 may be relatively large, and the weighted sense amplifier 405 may amplify the levels of the bit line BL1 and the bit line bar BLB1 to the core voltage VCORE and a ground voltage VSS by sensing the level difference.

As described above, the connection relationships among the memory cells, the word lines, and the sense amplifier between the first and second memory regions 400 and 220 may be the same as each other except that the word lines of each of the pairs of word lines SWL0 and SWL1, SWL2 and SWL3, and SWL4 and SWL5 are simultaneously activated according to a single address in the first memory region 400. That is to say, the connection relationships in each of the first and second memory regions 400 and 220 may be identically implemented. However, the second memory region 220 may enable each word line according to a single address while the first memory region 400 may simultaneously enable each pair of two word lines, i.e., the pair of the third and fourth word lines SWL2 and SWL3, in response to a single address.

As can be seen from FIGS. 5 and 11, the weighted sense amplifier 405 of the first memory region 400 may sense twice the voltage level of the bit lines versus the non-weighted sense amplifier 225 of the second memory region 220. Therefore, the reliability of the data readout from the first memory region 400 may have twice or more times the reliability of the data readout from the second memory region 220.

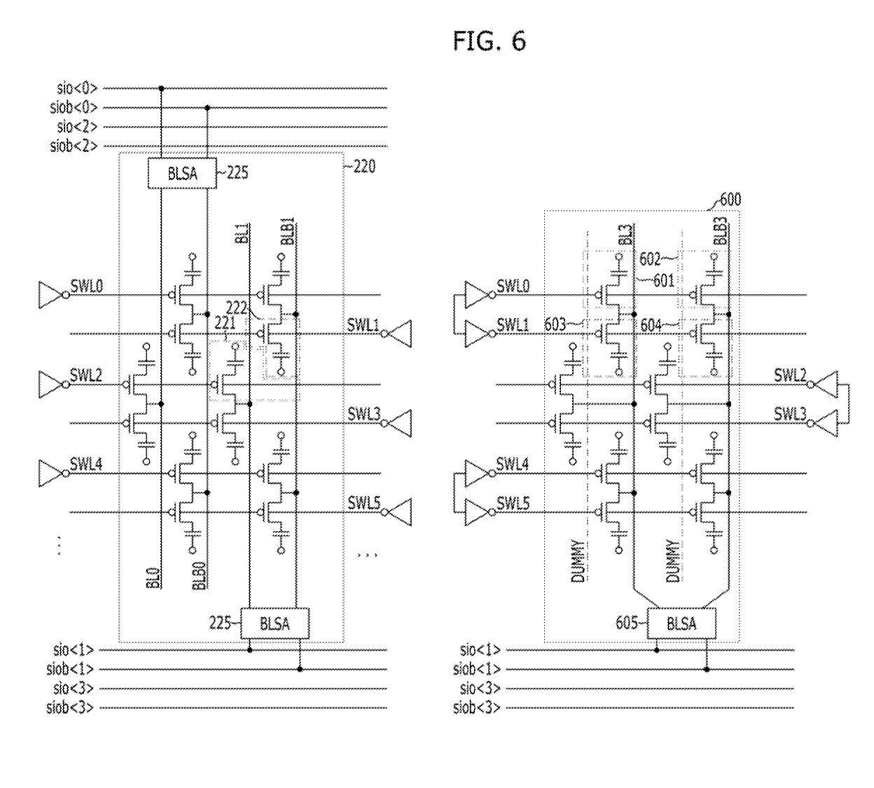

FIG. 6 is a circuit diagram illustrating a memory cell array of a semiconductor memory device in accordance with an exemplary embodiment of the present invention.

Referring to FIG. 6, the memory cell array of the semiconductor memory device may include first and second memory regions 600 and 620. For example, the first memory region 600 may include a weighted sense amplifier 605, a pair of first and third weighted memory cells 601 and 603, and a pair of second and fourth weighted memory cells 602 and 604. The pairs of weighted memory cells 601 and 603, and 602 and 604 may be coupled to the weighted sense amplifier 605, and pairs of word lines SWL0 and SWL1, SWL2 and SWL3, and SWL4 and SWL5.

The second memory region 220 220 may be the same as the second memory region described with reference to FIGS. 2 and 11.

The connection relationships among the memory cells, the word lines, and the sense amplifier between the first memory regions 200 and 600 shown in FIGS. 2 and 6 may be the same as each other except that the word lines of each of the pairs of word lines SWL0 and SWL1, SWL2 and SWL3, and SWL4 and SWL5 are simultaneously activated according to a single address in the first memory region 600 shown in FIG. 6.

The first memory region 600 may store a single datum in two or more memory cells simultaneously selected by the pair of word lines according to a single address (not shown).

The pair of first and third weighted memory cells 601 and 603 may be respectively coupled with the pair of first and second word lines SWL0 and SWL1, and a bit line BL3 therebetween, and may store the same data.

The pair of second and fourth weighted memory cells 602 and 604 may be respectively coupled with the pair of first and second word lines SWL0 and SWL1, and a bit line bar BLB3 therebetween, and may store the inverted version of the data stored in the pair of first and third weighted memory cells 601 and 603.

For example, the pair of first and second word lines SWL0 and SWL1 may be simultaneously selected and enabled in response to a single address. In other words, the two pairs of first to fourth weighted memory cells 601 to 604 may be simultaneously selected or not.

For example, with reference to the pairs of first and second word lines SWL0 and SWL1, the two pairs of first to fourth weighted memory cells 601 to 604 may be disposed on the bit line and bit line bar BL3 and BLB3.

The weighted sense amplifier 605 may sense and amplify a level difference between the data stored in each of the two pairs of first to fourth weighted memory cells 601 to 604 through the bit line BL3 and through the bit line bar BLB3.

Although each of the two pairs of first to fourth weighted memory cells 601 to 604 are coupled with the pair of first and second word lines SWL0 and SWL1 as described above, both of the two pairs of first to fourth weighted memory cells 601 to 604 are coupled with substantially a single word line since the pair of first and second word lines SWL0 and SWL1 are simultaneously enabled or disabled. In other words, when the pair of first and second word lines SWL0 and SWL1 are simultaneously enabled in response to a row address (not shown) applied from an exterior, the two pairs of first to fourth weighted memory cells 601 to 604 may be simultaneously selected. Since the pair of first and third weighted memory cells 601 and 603 are coupled with the bit line BL3, and the pair of second and fourth weighted memory cells 602 and 604 are coupled with the bit line bar BLB3, the data stored in the pair of first and third weighted memory cells 601 and 603 may be loaded on the bit line BL3 when the inverted data stored in the pair of second and fourth weighted memory cells 602 and 604 are loaded on the bit line bar BLB3.

The data stored in each of the two pairs of first to fourth weighted memory cells 601 to 604 have the same level while the data between the two pairs of first to fourth weighted memory cells 601 to 604 have the opposite level. For example, when the data stored in the first weighted memory cell 601 has a level corresponding to ‘1’, the data stored in the third weighted memory cell 603 may also have the level corresponding to ‘1’ while the data stored in each of the second and fourth weighted memory cells 602 and 604 may have the level corresponding to ‘0’.

Therefore, in the first memory region 600, each of the pair of word lines SWL0 and SWL1, SWL2 and SWL3, and SWL4 and SWL5 may simultaneously couple the two pairs of first to fourth weighted memory cells 601 to 604 respectively to the bit line BL3 and the bit line bar BLB3 of the weighted sense amplifier 405, which means that the data stored in the two pairs of first to fourth weighted memory cells 601 to 604 may be simultaneously loaded on the bit line BL3 and the bit line bar BLB3 of the weighted sense amplifier 405. On the other hand, in the second memory region 220, each of the pairs of word lines SWL0 and SWL1, SWL2 and SWL3, and SWL4 and SWL5 may couple the pair of the non-weighted memory cells exclusively to one of the bit line BL0 to BL2 and the bit line BLB0 to BLB2, which means that the data stored in the first and second non-weighted memory cells 221 and 222 may be exclusively and alternately loaded between the bit line BL0 to BL2 and the bit line BLB0 to BLB2 of the non-weighted sense amplifier 225.

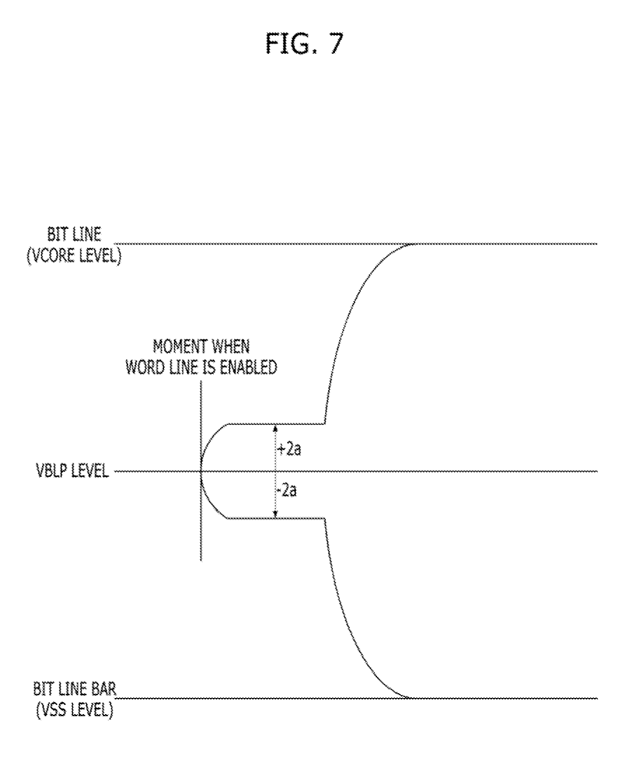

FIG. 7 is a waveform diagram illustrating an operation of a first memory region shown in FIG. 6.

As shown in FIG. 7, in response to the activated pair of first and second word lines SWL0 and SWL1, a voltage level of the bit line BL3 may increase by twice the predetermined amount of “+2a” from a bit line precharge voltage VBLP, and a level of the bit line bar BLB3 may decrease by twice of the predetermined amount of “−2a” from the bit line precharge voltage VBLP. Therefore, a level difference between the bit line BL3 and the bit line bar BLB3 may be relatively large, and the weighted sense amplifier 605 may amplify the levels of the bit line BL3 and the bit line bar BLB3 to the core voltage VCORE and the ground voltage VSS by sensing the level difference.

As described above, the connection relationships among the memory cells, the word lines, and the sense amplifier between the first memory regions 200 and 600 shown in FIGS. 2 and 6 may be the same as each other except that the word lines of each of the pairs of word line SWL0 and SWL1, SWL2 and SWL3, and SWL4 and SWL5 are simultaneously activated according to a single address in the first memory region 600. For example, in the first memory region 600, each of the pairs of first to fourth weighted memory cells 601 to 604 may be disposed at every cross point of the pairs of word lines SWL0 and SWL1, SWL2 and SWL3, and SWL4 and SWL5 and the bit lines BL3 and BLB3 with reference to the single weighted sense amplifier 605. For example, in the second memory region 220, pairs of the non-weighted memory cells may be alternately disposed between the bit line BL1 and the bit line bar BLB1 at cross points formed by pairs of the word lines and the bit line BL1 and the bit line bar BLB1 with reference to the single non-weighted sense amplifier 225. For example, with reference to the pair of third and fourth word lines SWL2 and SWL3, the non-weighted memory cells may be disposed only on the bit lines BL0 and BL1. For example, with reference to the pairs of first and second, and fifth and sixth word lines SWL0 and SWL1, and SWL4 and SWL5, the non-weighted memory cells may be disposed only on the bit line bars BLB0 and BLB1.

Similarly to the semiconductor memory device illustrated in FIG. 2, the first memory region 600 has to go through a completely different fabrication process from the second memory region 620 in order to be disposed. Furthermore, similarly to the semiconductor memory device illustrated in FIG. 4, the control of the first memory region 600 has to be completely separated from the control of the second memory region 620. The semiconductor memory device described with reference to FIGS. 6 and 7 may secure reliable data readout since a single datum is stored in the two pairs of memory cells.

As can be seen from FIGS. 7 and 11, the operation of the weighted sense amplifier 605 of the first memory region 600 may sense four times as great of voltage level of the bit lines a the non-weighted sense amplifier 225 of the second memory region 220. Therefore, the reliability of the data readout from the first memory region 600 may be four times or more as reliable as the data readout from the second memory region 220.

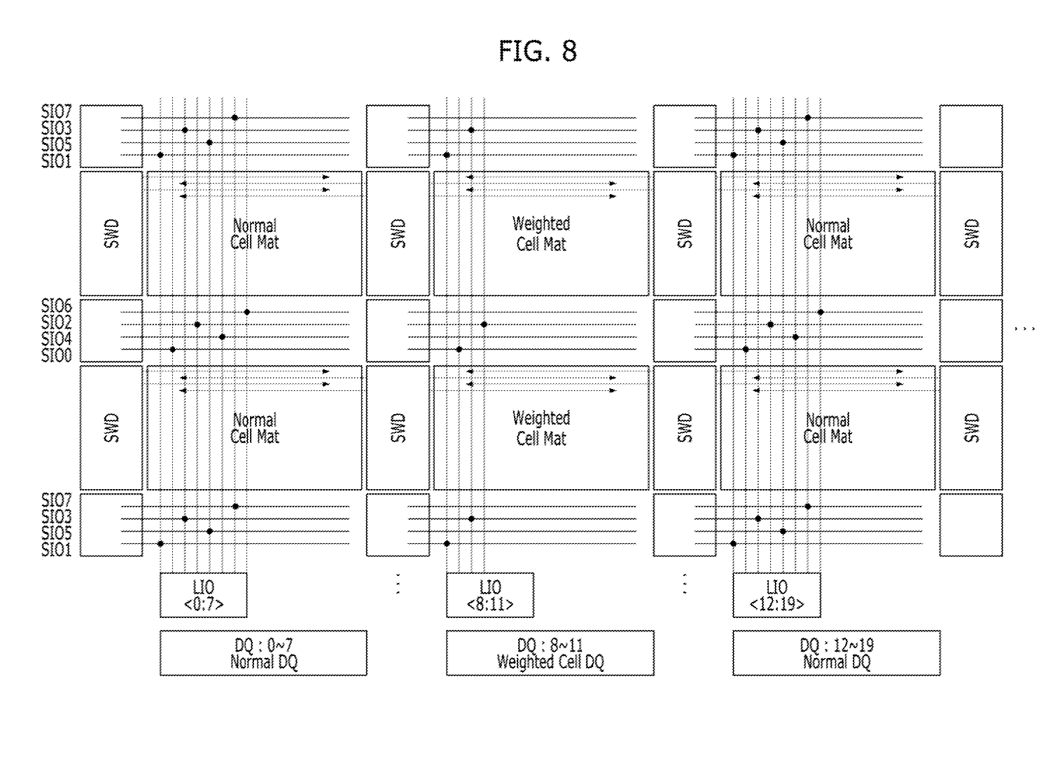

FIGS. 8 to 10 are layouts illustrating a semiconductor memory device in accordance with various exemplary embodiments of the present invention. In accordance with various exemplary embodiments of the present invention, each layout shown in FIGS. 8 to 10 may be combined with each memory cell array described with reference to FIGS. 2 to 7.

FIGS. 8 to 10 shows the first memory regions 200, 400 and 600 and the second memory region 220 described with reference to FIGS. 2 to 7 as ‘weighted cell mats’ and ‘normal cell mats’, respectively.

To be specific, the first memory regions 200, 400 and 600 input/output data through a first path LIO<8:11>→DQ: 8 to 11.

The second memory region 220 may input/output data through second paths LIO<0:7>→DQ: 0 to 7 and LIO<12:19>→DQ: 12 to 19.

The first memory regions 200, 400 and 600 and the second memory region 220 may have different data input/output paths, respectively.

Therefore, the first memory regions 200, 400 and 600 and the second memory region 220 may simultaneously operate. In other words, the first memory regions 200, 400 and 600 and the second memory region 220 may be simultaneously selected in response to one address (not shown). While the first memory regions 200, 400 and 600 and the second memory region 220 are simultaneously selected, the data of the first memory regions 200, 400 and 600 may be inputted/outputted through the first path LIO<8:11>→DQ: 8 to 11, and the data of the second memory region 220 may be inputted/outputted through the second paths LIO<0:7>→DQ: 0 to 7 and LIO<12:19>→DQ: 12 to 19.

The data inputted/outputted through the first path LIO<8:11>→DQ: 8 to 11 and the data inputted/outputted through the second paths LIO<0:7>→DQ: 0 to 7 and LIO<12:19>→DQ: 12 to 19 may be inputted/outputted at the same time. Simultaneously, the reliability of the data inputted/outputted through the first path LIO<8:11>→DQ: 8 to 11 may be more than twice as reliable as the data inputted/outputted through the second paths LIO<0:7>→DQ: 0 to 7 and LIO<12:19>→DQ: 12 to 19.

For this reason, it may be effective to use a portion of the data whose importance is relatively high to be simultaneously inputted/outputted is inputted/outputted through the first path LIO<8:11>→DQ: 8 to 11, and the other data whose importance is relatively low are inputted/outputted through the second paths LIO<0:7>→DQ: 0 to 7 and LIO<12:19>→DQ: 12 to 19.

For example, it may be highly effective to use an Error Correcting Code (ECC) for correcting an error of the data which is inputted/outputted through the first path LIO<8:11>→DQ: 8 to 11.

Whereas the data of four bits are inputted/outputted in parallel through the first path LIO<8:11>→DQ: 8 to 11, the data of 16 bits may be inputted/outputted in parallel through the second paths LIO<0:7>→DQ: 0 to 7 and LIO<12:19>→DQ: 12 to 19. The reason why there is a difference is that the reliability of the data to be stored in the first memory regions 200, 400 and 600 has to be higher than double the reliability of the data to be stored in the second memory region 220. Therefore, when it is assumed that occupying areas of the first memory regions 200, 400 and 600 are the same as occupying areas of the second memory region 220, the amount of storable data of the first memory regions 200, 400 and 600 may be approximately half the storable data of the second memory region 220. The sizes of the paths where the data may be simultaneously inputted/outputted in the first memory regions 200, 400 and 600 and the second memory region 220 respectively may decrease by half.

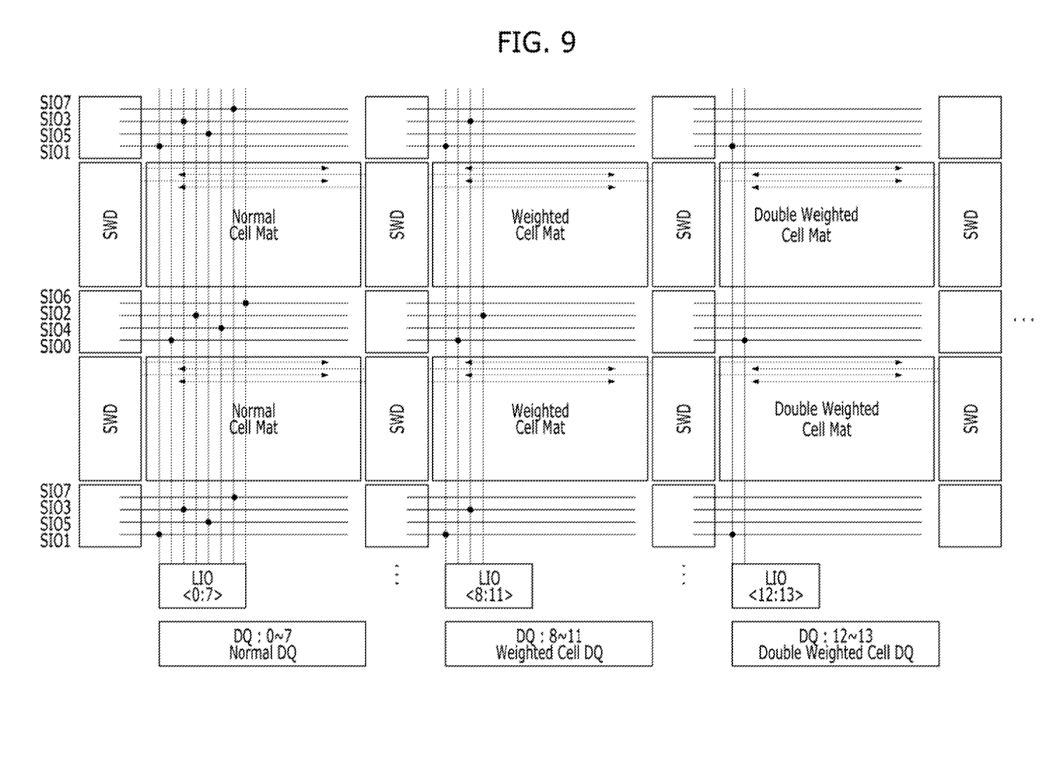

FIG. 9 is a layout illustrating a semiconductor memory device in accordance with an exemplary embodiment of the present invention.

FIG. 9 shows the first memory regions 200 and 400 as the ‘weighted cell mats’, and the first memory region 600 as ‘double weighted cell mats’.

In the description of FIG. 9 below, the memory regions represented by ‘weighted cell mats’ are described as ‘normal first memory regions 200 and 400’ and the memory regions represented by ‘double weighted cell mats’ are described as ‘double first memory regions 600’ in order to distinguish the memory regions represented by ‘weighted cell mats’ from the memory regions represented by ‘double weighted cell mats’.

To be specific, the normal first memory regions 200 and 400 may input/output data through a first path LIO<8:11>→DQ: 8 to 11.

The double first memory region 600 may input/output data through a second path LIO<12:13>→DQ: 12 and 13.

The second memory region 220 may input/output data through a third path LIO<0:7>→DQ: 0 to 7.

The normal first memory regions 200 and 400, the double first memory region 600 and the second memory region 220 may have different data input/output paths, respectively.

Therefore, the normal first memory regions 200 and 400, the double first memory region 600 and the second memory region 220 may simultaneously operate. In other words, the normal first memory regions 200 and 400, the double first memory region 600 and the second memory region 220 may be simultaneously selected in response to one address (not shown). While the normal first memory regions 200 and 400, the double first memory region 600 and the second memory region 220 are simultaneously selected, the data of the normal first memory regions 200 and 400 may be inputted/outputted just through the first path LIO<8:11>→DQ: 8 to 11, and the data of the double first memory region 600 may be inputted/outputted just through the second path LIO<12:13>→DQ: 12 and 13, and the data of the second memory region 220 may be inputted/outputted just through the third path LIO<0:7>→DQ: 0 to 7.

Therefore, the data inputted/outputted through the first path LIO<8:11>→DQ: 8 to 11, the data inputted/outputted through the second path LIO<12:13>→DQ: 12 and 13, and the data inputted/outputted through the third path LIO<0:7>→DQ: 0 to 7 may be inputted/outputted at the same time. Simultaneously, the reliability of the data inputted/outputted through the first path LIO<8:11>→DQ: 8 to 11 may be higher than double the reliability of the data inputted/outputted through the third path LIO<0:7>→DQ: 0 to 7, and the reliability of the data inputted/outputted through the second path LIO<12:13>→DQ: 12 and 13 may be higher than double the reliability of the data inputted/outputted through the first path LIO<8:11>→DQ: 8 to 11.

For this reason, it may be effective to use a portion of the data whose importance is relatively high among the data to be simultaneously inputted/outputted through the first path LIO<8:11>→DQ: 8 to 11 or the second path LIO<12:13>→DQ: 12 and 13, and the other data whose importance is relatively low may be inputted/outputted through the third path LIO<0:7>→DQ: 0 to 7.

For example, it may be highly effective to use the paths in such a way that an Error Correcting Code (ECC) for correcting an error of the data which is inputted/outputted through the third path LIO<0:7>→DQ: 0 to 7 may be inputted/outputted through the first path LIO<8:11>→DQ: 8 to 11 and an Error Correcting Code (ECC) for correcting an error of the data which is inputted/outputted through the first path LIO<8:11>→DQ: 8 to 11 may be inputted/outputted through the second path LIO<12:13>→DQ: 12 and 13.

Whereas the data of four bits are inputted/outputted in parallel through the first path LIO<8:11>→DQ: 8 to 11, the data of 2 bits may be inputted/outputted in parallel through the second path LIO<12:13>→DQ: 12 and 13, and the data of 8 bits may be inputted/outputted in parallel through the third path LIO<0:7>→DQ: 0 to 7. The reason why there is a difference is that the reliability of the data to be stored in the normal first memory regions 200 and 400 has to be more than twice high as the reliability of the data to be stored in the second memory region 220, and the data to be stored in the double first memory region 600 has to be more than twice as high as the reliability of the data to be stored in the normal first memory regions 200 and 400. Therefore, when it is assumed that occupied areas of the normal first memory regions 200 and 400 are the same as the occupied areas of the double first memory region 600 and occupied areas of the second memory region 220, the amount of storable data of the normal first memory regions 200 and 400 may be approximately half the amount of storable data of the second memory region 220, and the number of the storable data of the double first memory region 600 may be approximately a quarter of the amount of the storable data of the second memory region 220. The sizes of the paths where the data may be simultaneously inputted/outputted in the normal first memory regions 200 and 400, the double first memory region 600 and the second memory region 220, respectively may decrease by half or a quarter.

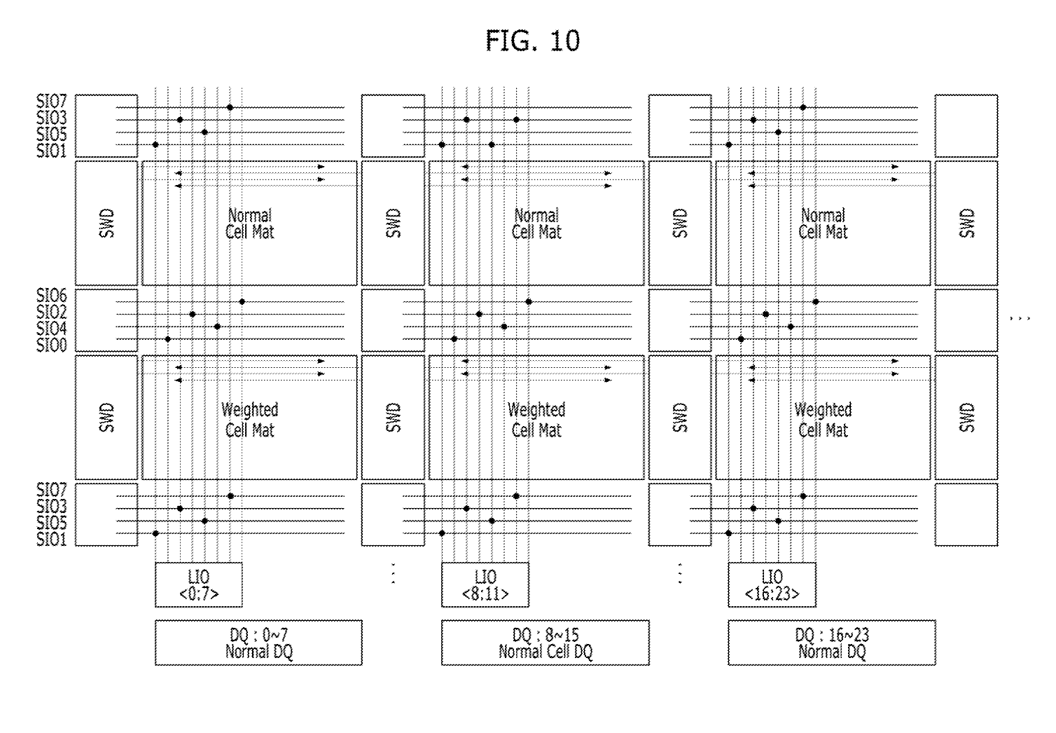

FIG. 10 is a layout illustrating a semiconductor memory device in accordance with an exemplary embodiment of the present invention.

To be specific, the first memory regions 200, 400 and 600 and the second memory region 220 may input/output data through common paths LIO<0:7>→DQ: 0 to 7, LIO<8:15>→DQ: 8 to 15 and LIO<16:23>→DQ: 16 to 23. In other words, the first memory regions 200, 400 and 600 may input/output data through the common paths LIO<0:7>→DQ: 0 to 7, LIO<8:15>→DQ: 8 to 15 and 10<16:23>→DQ: 16 to 23, and the second memory region 220 may input/output data through the common paths LIO<0:7>→DQ: 0 to 7, LIO<8:15>→DQ: 8 to 15 and LIO<16:23>→DQ: 16 to 23.

The first memory regions 200, 400 and 600 and the second memory region 220 may share the same data input/output paths.

Therefore, the first memory regions 200, 400 and 600 and the second memory region 220 may not simultaneously operate. In other words, one region between the first memory regions 200, 400 and 600 and the second memory region 220 may be selected in response to one address (not shown), and the data of the selected region is input/outputted through the common paths 10<0:7>→DQ: 0 to 7, LIO<8:15>→DQ: 8 to 15 and LIO<16:23>→DQ: 16 to 23.

Therefore, the data inputted/outputted in the first memory regions 200, 400 and 600 and the data inputted/outputted in the second memory region 220 may be inputted/outputted at different times. Simultaneously, the reliability of the data inputted/outputted through the common paths LIO<0:7>→DQ: 0 to 7, LIO<8:15>→DQ: 8 to 15 and LIO<16:23>→DQ: 16 to 23 may be different based on whether the first memory regions 200, 400 and 600 are selected or the second memory region 220 is selected inside the semiconductor memory device.

For this reason, it may be applicable to a semiconductor memory device which has high reliability data in one section and low reliability data in another section, based on operation options.

When it is assumed that occupying areas of the first memory regions 200, 400 and 600 are the same as occupying areas of the second memory region 220, the amount of storable data of the first memory regions 200, 400 and 600 may be approximately half the amount of storable data of the second memory region 220.

The way that the first memory regions 200, 400 and 600 and the second memory region 220 operate in a form of sharing the common paths LIO<0:7>→DQ: 0 to 7, LIO<8:15>→DQ: 8 to 15 and LIO<16:23>→DQ: 16 to 23 as shown in FIG. 10 may be extended to the way that the first memory regions 200, 400 and 600 are divided into normal first memory regions 200 and 400 and double first memory region 600, and the normal first memory regions 200 and 400, the double first memory region 600, and the second memory region 220 input/output data by sharing the common paths LIO<0:7>→DQ: 0 to 7, LIO<8:15>→DQ: 8 to 15 and LIO<16:23>→DQ: 16 to 23.

Referring back to FIGS. 8 to 10, the memory regions ‘weighted cell mats’ which are classified as the first memory regions 200, 400 and 600 and the memory regions ‘normal cell mats’ which are classified as the second memory region 220 may be included in the memory array in diverse forms.

This means that an address may not be set up differently from when accessing the second memory region 220 in order to access the first memory regions 200, 400 and 600 when the semiconductor memory device is to be accessed from the outside. In other words, a normal address which is accessible to all the memory cells included in the memory array may be inputted, similarly to a typical semiconductor memory device, when the semiconductor memory device is accessed from the outside. Afterward, it is possible to access the first memory regions 200, 400 and 600 and the second memory region 220 in the semiconductor memory device based on the value of the address which is inputted.

Particularly, since the first memory regions 200, 400 and 600 and the second memory region 220 are always selected together in the structures as shown in FIGS. 8 and 9, it is not possible to access the first memory regions 200, 400 and 600 and the second memory region 220 separately by intent from the outside. In other words, there is no need to know the internal structure of the semiconductor memory device in advance from the outside.

Since the first memory regions 200, 400 and 600 are selected separately from the second memory region 220 in the structure as shown in FIG. 10, it is possible to access the first memory regions 200, 400 and 600 and the second memory region 220 separately by intent from the outside. In other words, it is possible to selectively access the first memory regions 200, 400 and 600 and the second memory region 220 based on the importance of the data which is inputted/outputted from the outside.

In accordance with the various exemplary embodiments of the present invention as described above, the data whose importance is relatively high may be readout in such a manner that the data whose importance is relatively high is stored simultaneously in two or more cells, and the data whose importance is relatively low may be stored in one cell.

The reliability of all the data which is inputted/outputted may be improved through such a way of storing the data by classifying a normal data among the inputted/outputted data into the data whose importance is relatively low, and by classifying an Error Correcting Code (ECC) for correcting an error of the normal data into the data whose importance is relatively high.

While the present invention has been described with respect to specific embodiments, it is noted that the embodiments of the present invention are not restrictive but descriptive. Further, it is noted that the present invention may be achieved in various ways through substitution, change, and modification, by those skilled in the art without departing from the scope of the present invention as defined by the following claims.

For example, the structures of all the semiconductor memory devices in the embodiments of the present invention are described in a form of a folded bit line structure where a bit line and a bit line bar are coupled with one bit line sense amplifier. However, the structure of a semiconductor memory device having an open bit line structure where a bit line and a bit line bar are coupled with different bit line sense amplifiers, respectively, may be included in the scope of the present invention. Therefore, the semiconductor memory device in accordance with the scope of the present invention may include a semiconductor memory device where the cell architecture size is designed based on 8F² and a semiconductor memory device where the cell architecture size is designed based on 6F².

Also, dispositions and types of the logic gates and transistors described in the aforementioned embodiments may be implemented differently based on a polarity of an inputted signal.

What is claimed is:

1. A semiconductor memory device, comprising:
a first memory region including a plurality of first memory cells, two or more of which are simultaneously selected by a single address, and stores a first single datum; and
a second memory region including a plurality of second memory cells, each of which is selected by the single address, and stores a second single datum.

2. The semiconductor memory device of claim 1, wherein each of the first and second memory regions includes a dedicated path, through which each of the first and second memory regions transfers the corresponding single datum stored therein.

3. The semiconductor memory device of claim 2, wherein the first and second memory regions simultaneously transfer the corresponding single datum stored therein through the corresponding dedicated paths in response to the single address.

4. The semiconductor memory device of claim 1, wherein the first and second memory regions share a common path, through which each of the first and second memory regions transfers the corresponding single datum stored therein.

5. The semiconductor memory device of claim 4, wherein one of the first and second memory regions transfers the corresponding single datum stored therein through the common path in response to the single address.

6. The semiconductor memory device of claim 1, wherein the first memory region includes:
a first weighted memory cell coupled with a word line and a bit line therebetween, and suitable for storing the first single datum;
a second weighted memory cell coupled with the word line and a bit line bar therebetween, and suitable for storing an inverted version of the first single datum; and
a weighted sense amplifier having the bit line and the bit line bar, and suitable for sensing and amplifying a level difference between the first single datum and the inverted version of the first single datum.

7. The semiconductor memory device of claim 1,
wherein the first memory region includes:
a first weighted memory cell coupled with a first word line and a bit line therebetween, and suitable for storing the first single datum;
a second weighted memory cell coupled with a second word line and the bit line therebetween, and suitable for storing the first single datum; and
a weighted sense amplifier having the bit line and a bit line bar, and suitable for sensing and amplifying a level difference between the first single datum stored in the first and second weighted memory cells, and
wherein the first and second word lines are simultaneously selected in response to the single address.

8. The semiconductor memory device of claim 1,
wherein the first memory region includes:
a pair of first and third weighted memory cells coupled with a pair of first and second word lines and a bit line therebetween, and suitable for storing the first single datum;
a pair of second and fourth weighted memory cells coupled with the pair of first and second word lines and a bit line bar therebetween, and suitable for storing an inverted version of the first single datum; and
a weighted sense amplifier having the bit line and the bit line bar, and suitable for sensing and amplifying a level difference between the first single datum stored in the pair of first and third weighted memory cells and the inverted version of the first single datum stored in the pair of second and fourth weighted memory cells, and
wherein the pair of first and second word lines are simultaneously selected in response to the single address.

9. The semiconductor memory device of claim 1,
wherein the second memory region includes:
first and second non-weighted memory cells coupled with first and second word lines and a bit line therebetween, and suitable for storing the second single datum;
third and fourth non-weighted memory cells coupled with third and fourth word lines and a bit line bar therebetween, and suitable for storing the second single datum; and
an non-weighted sense amplifier having the bit line and the bit line bar, and suitable for sensing and amplifying a level difference between the second single datum stored in each of the first to fourth non-weighted memory cells, and
wherein each of the first to fourth word lines is independently selected in response to the single address.

10. The semiconductor memory device of claim 1, wherein the first single datum is an Error Correcting Code (ECC) for correcting an error that occurred in the second single datum.

11. A semiconductor memory device, comprising:
a first memory region including a plurality of first memory cells, two of which are simultaneously selected by a single address, and stores a first single datum;
a second memory region including a plurality of second memory cells, four of which are simultaneously selected by a single address, and stores a second single datum; and
a third memory region including a plurality of third memory cells, each of which is selected by a single address, and stores a third single datum.

12. The semiconductor memory device of claim 11, wherein each of the first to third memory regions includes a dedicated path, through which each of the first to third memory regions transfers the corresponding single datum stored therein.

13. The semiconductor memory device of claim 12, wherein the first to third memory regions simultaneously transfer the corresponding single datum stored therein through the corresponding dedicated paths in response to the single address.

14. The semiconductor memory device of claim 11, wherein the first to third memory regions share a common path, through which each of the first to third memory regions transfers the corresponding single datum stored therein.

15. The semiconductor memory device of claim 14, wherein one of the first to third memory regions transfers the corresponding single datum stored therein through the common path in response to the single address.

16. The semiconductor memory device of claim 11, wherein the first memory region includes:
a first weighted memory cell coupled with a word line and a bit line therebetween, and suitable for storing the first single datum;
a second weighted memory cell coupled with the word line and a bit line bar therebetween, and suitable for storing an inverted version of the first single datum; and
a weighted sense amplifier having the bit line and the bit line bar, and suitable for sensing and amplifying a level difference between the first single datum and the inverted version of the first single datum.

17. The semiconductor memory device of claim 11,
wherein the first memory region includes:
a first weighted memory cell coupled with a first word line and a bit line therebetween, and suitable for storing the first single datum;
a second weighted memory cell coupled with a second word line and the bit line therebetween, and suitable for storing the first single datum; and
a weighted sense amplifier having the bit line and a bit line bar, and suitable for sensing and amplifying a level difference between the first single datum stored in the first and second weighted memory cells, and
wherein the first and second word lines are simultaneously selected in response to the single address.

18. The semiconductor memory device of claim 11,
wherein the second memory region includes:
a pair of first and third weighted memory cells coupled with a pair of first and second word lines and a bit line therebetween, and suitable for storing the second single datum;
a pair of second and fourth weighted memory cells coupled with the pair of first and second word lines and a bit line bar therebetween, and suitable for storing an inverted version of the second single datum; and
a weighted sense amplifier having the bit line and the bit line bar, and suitable for sensing and amplifying a level difference between the second single datum stored in the pair of first and third weighted memory cells and the inverted version of the second single datum stored in the pair of second and fourth weighted memory cells, and
wherein the pair of first and second word lines are simultaneously selected in response to the single address.

19. The semiconductor memory device of claim 11,
wherein the third memory region includes:
first and second non-weighted memory cells coupled with first and second word lines and a bit line therebetween, and suitable for storing the third single datum;
third and fourth non-weighted memory cells coupled with third and fourth word lines and a bit line bar therebetween, and suitable for storing the third single datum; and
a non-weighted sense amplifier having the bit line and the bit line bar, and suitable for sensing and amplifying a level difference between the third single datum stored in each of the first to fourth non-weighted memory cells, and
wherein each of the first to fourth word lines is independently selected in response to the single address.

20. The semiconductor memory device of claim 11, wherein the first single datum is a first Error Correcting Code (ECC) for correcting an error that occurred in the third single datum, and the second single datum is a second Error Correcting Code (ECC) for correcting an error that occurred in the first single datum.
